(19) United States
(12) Patent Application Publication
(10) Pub. No.: US 2017/0077128 A1
(43) Pub. Date: Mar. 16, 2017

(54) SEMICONDUCTOR MEMORY DEVICE

(71) Applicant: Kabushiki Kaisha Toshiba, Minato-ku (JP)

(72) Inventor: Yasuhiro UCHIYAMA, Yokkaichi (JP)

(73) Assignee: Kabushiki Kaisha Toshiba, Minato-ku (JP)

(21) Appl. No.: 15/049,907

(22) Filed: Feb. 22, 2016

Related U.S. Application Data
(60) Provisional application No. 62/216,849, filed on Sep. 10, 2015.

(51) Int. Cl. H01L 27/115; H01L 23/522

(52) U.S. Cl. CPC H01L 27/11582; H01L 27/11568; H01L 23/5226

(57) ABSTRACT

According to one embodiment, a semiconductor memory device comprises a first semiconductor region of n-type conductivity, a second semiconductor region of p-type conductivity, a third semiconductor region of n-type conductivity, a stacked body, a semiconductor pillar, a first insulating layer, a charge storage layer, a second insulating layer, a first conductive portion, and a second conductive portion. The semiconductor pillar extends in the stacked body in a direction in which the conductive layers and the insulating layers are stacked. The semiconductor pillar is connected to the first semiconductor region. The first conductive portion extends in the stacked body in the stacking direction. The first conductive portion is connected to the second semiconductor region. The second conductive portion extends in the stacked body in the stacking direction. The second conductive portion is connected to the third semiconductor region.

### CROSS-REFERENCE TO RELATED APPLICATIONS

This application is based upon and claims the benefit of priority from U.S. Provisional Patent Application 62/216,849, filed on Sep. 10, 2015; the entire contents of which are incorporated herein by reference.

### FIELD

Embodiments described herein relate generally to a semiconductor memory device.

### BACKGROUND

A semiconductor memory device has been proposed in which memory cells are three-dimensionally integrated. The semiconductor memory device can be formed as follows: insulating films and electrode films are alternately stacked to form a stacked body; a through hole is formed in the stacked body; a memory film that can store charge is formed on the inner surface of the through hole; and a semiconductor pillar is formed in the through hole. The memory cell can be formed between the semiconductor pillar and an electrode film by the above-mentioned process.

A technique is required which can accurately read stored information in the semiconductor memory device.

### BRIEF DESCRIPTION OF THE DRAWINGS

FIG. 1 is a cross-sectional view of the semiconductor memory device according to the embodiment;

FIG. 2 is a cross-sectional view taken along the line A-A′ of FIG. 1;

FIG. 3A and FIG. 3B are enlarged cross-sectional views of a portion of the semiconductor memory device according to the embodiment;

FIG. 4 is an enlarged cross-sectional view of another portion of the semiconductor memory device according to the embodiment;

FIG. 5A to FIG. 11B are cross-sectional views of a manufacturing process of the semiconductor memory device according to the embodiment.

FIG. 12 is a cross-sectional view of a semiconductor memory device according to the comparative example; and

FIG. 13 is a diagram for describing the problems of the semiconductor memory device according to the comparative example.

### DETAILED DESCRIPTION

According to one embodiment, a semiconductor memory device comprises a first semiconductor region of n-type conductivity, a second semiconductor region of p-type conductivity, a third semiconductor region of n-type conductivity, a stacked body, a semiconductor pillar, a first insulating layer, a charge storage layer, a second insulating layer, a first conductive portion, and a second conductive portion. The second semiconductor region is provided on the first semiconductor region. The third semiconductor region is provided on the first semiconductor region with separation from the second semiconductor region. The stacked body is provided on the semiconductor layer. The stacked body includes a plurality of conductive layers and a plurality of insulating layers. The plurality of conductive layers and the plurality of insulating layers are alternately provided. The semiconductor pillar extends in the stacked body in a direction in which the plurality of conductive layers and the plurality of insulating layers are stacked. The semiconductor pillar is connected to the first semiconductor region. The first insulating layer is provided between the stacked body and the semiconductor pillar. The charge storage layer is provided between the stacked body and the first insulating layer. At least a portion of the second insulating layer is provided between the stacked body and the charge storage layer. The first conductive portion extends in the stacked body in the stacking direction. The first conductive portion is connected to the second semiconductor region. The second conductive portion extends in the stacked body in the stacking direction. The second conductive portion is connected to the third semiconductor region.

Hereinafter, each embodiment of the invention will be described with reference to the drawings.

The drawings are schematic or conceptual and, for example, the relationships between the thicknesses and widths of portions and the proportions of sizes among portions are not necessarily the same as the actual values thereof. Further, the dimensions and the proportions may be illustrated differently among the drawings, even for identical portions.

In the specification and the drawings, the same components as previously described are denoted by the same reference numerals and the detailed description thereof will not be repeated.

In the description of each embodiment, an XYZ rectangular coordinate system is used. It is assumed that two directions which are perpendicular to each other in a direction parallel to the main surface of a substrate are referred to as an X-direction (first direction) and a Y-direction (second direction) and a direction perpendicular to both the X-direction and the Y-direction is referred to as a Z-direction.

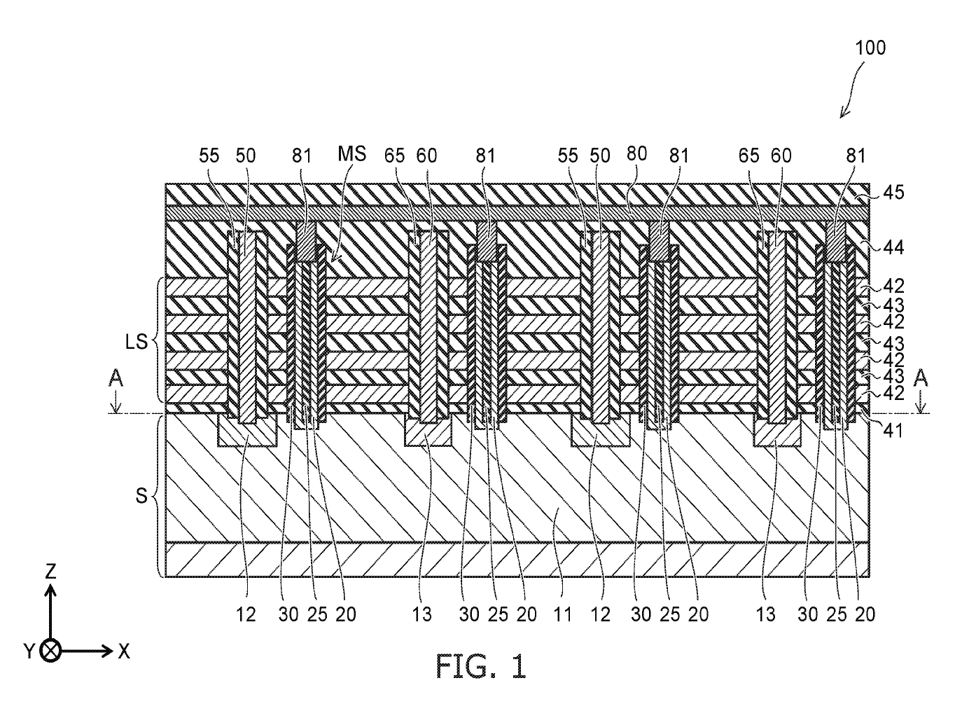

A semiconductor memory device 100 according to an embodiment will be described with reference to FIG. 1 to FIG. 4.

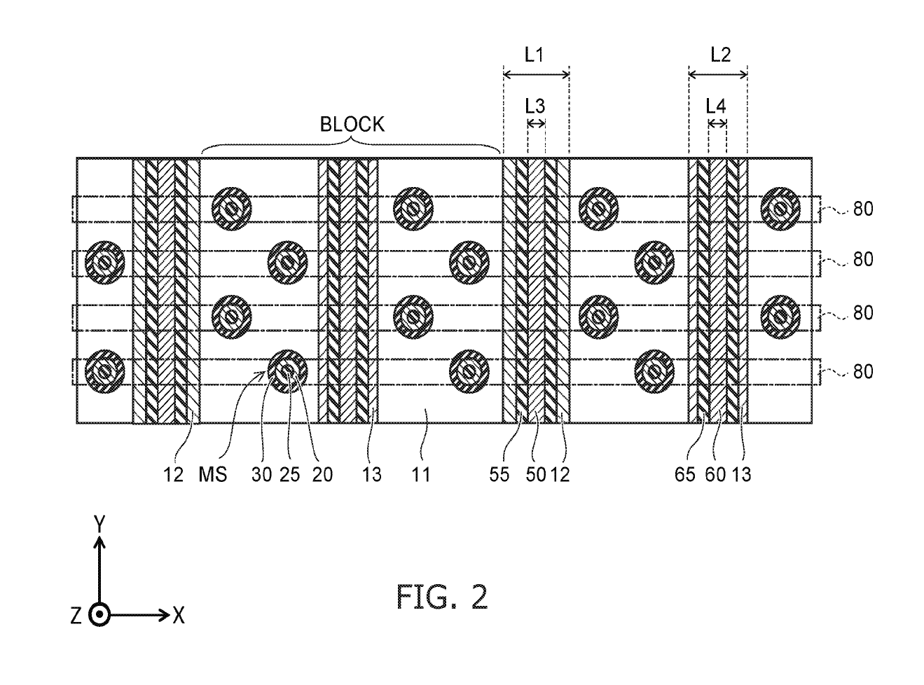

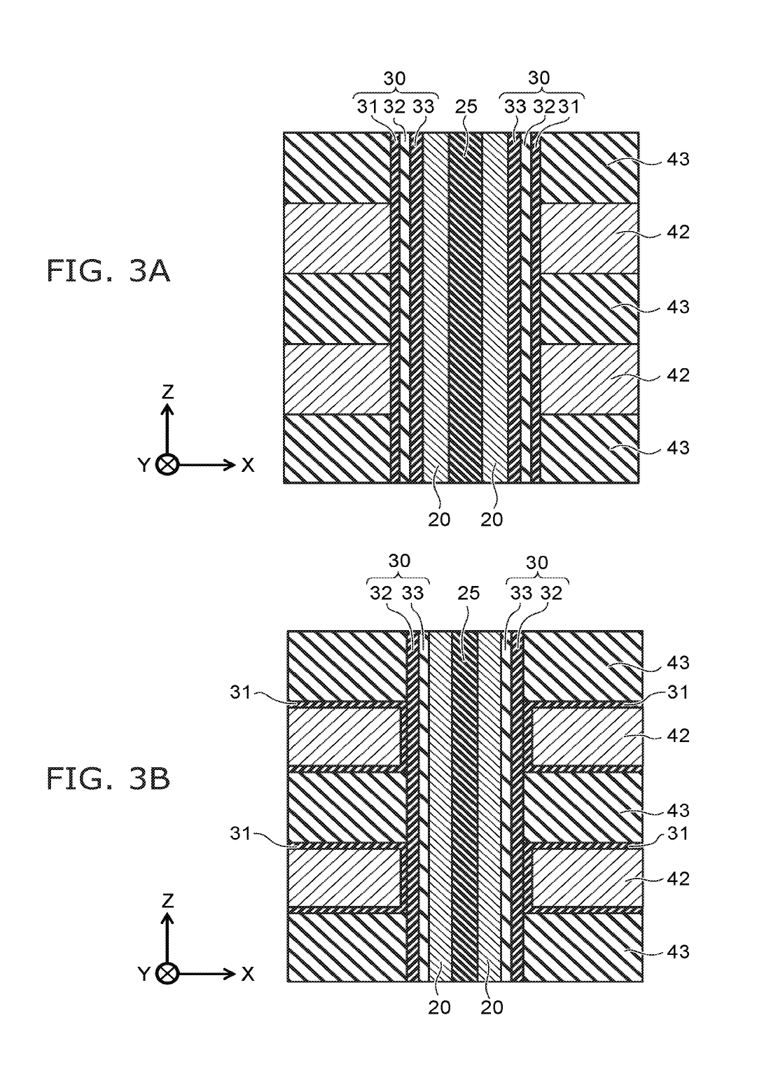

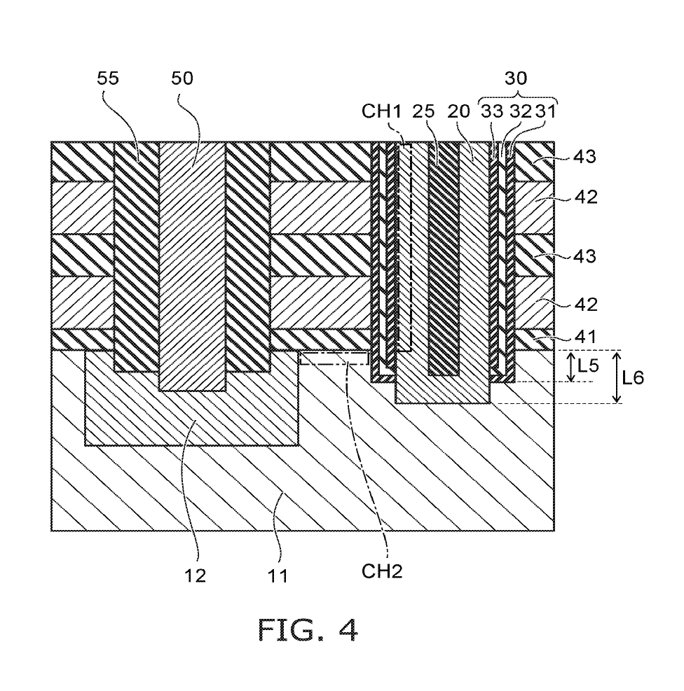

FIG. 1 is a cross-sectional view of the semiconductor memory device 100 according to the embodiment. FIG. 2 is a cross-sectional view taken along the line A-A′ of FIG. 1. FIG. 3A and FIG. 3B are enlarged cross-sectional views of a portion of the semiconductor memory device 100 according to the embodiment. FIG. 4 is an enlarged cross-sectional view of another portion of the semiconductor memory device 100 according to the embodiment.

In FIG. 2, a position that overlaps a bit line 80 in the Z-direction is represented by a dashed line in order to describe the structure of the semiconductor memory device 100.

The semiconductor memory device 100 according to the embodiment is, for example, a non-volatile semiconductor memory device which can electrically erase or write data and can retain the stored content even when power is turned off.

For example, as illustrated in FIG. 1, the semiconductor memory device 100 is provided on a semiconductor substrate S (hereinafter, referred to as a substrate S). An n-type semiconductor region 11, a p-type semiconductor region 12, and an n-type semiconductor region 13 are provided in the surface of the substrate S. The p-type semiconductor region 12 is provided in a surface layer of the n-type semiconductor region 11. The n-type semiconductor region 13 is provided in the surface layer of the n-type semiconductor region 11. The n-type semiconductor region 13 is provided so as to be separated from the p-type semiconductor region 12 in the X-direction.

The p-type carrier density of the p-type semiconductor region 12 is higher than, for example, the n-type carrier density of the n-type semiconductor region 11. The n-type carrier density of the n-type semiconductor region 13 is higher than, for example, the n-type carrier density of the n-type semiconductor region 11. The maximum value of the n-type carrier density of the n-type semiconductor region 13 is greater than, for example, the maximum value of the p-type carrier density of the p-type semiconductor region 12.

An insulating layer 41, a plurality of conductive layers 42, a plurality of insulating layers 43, and an insulating layer 44 are provided on the n-type semiconductor region 11. The conductive layers 42 and the insulating layers 43 are alternately stacked. The conductive layer 42 has sufficient conductivity to function as a gate electrode of a memory cell.

A semiconductor pillar 20 and a memory layer 30 extend in a stacked body LS that includes the plurality of conductive layers and the plurality of insulating layers 43 in a direction (Z-direction) in which the conductive layers 42 and the insulating layers 43 are stacked. The semiconductor pillar 20 and the memory layer 30 also extend in the insulating layer 41. At least a portion of the memory layer 30 is located between a portion of the semiconductor pillar 20 and the stacked body LS and between a portion of the semiconductor pillar 20 and the insulating layer 41.

The memory layer 30 and the conductive layer 42 form, for example, a charge-trap memory cell. The memory cells formed by the memory layer 30 and the conductive layers 42 are connected in series to each other by the semiconductor pillar 20 to form a memory string MS.

For example, as illustrated in FIG. 1, an insulating portion 25 may be provided inside the semiconductor pillar 20. In this case, a portion of the semiconductor pillar 20 and a portion of the memory layer 30 are provided, for example, between a portion of the insulating portion 25 and the stacked body LS and between a portion of the insulating portion 25 and the insulating layer 41. Instead of the insulating portion 25, a gap may be provided inside the semiconductor pillar 20. Alternatively, the insulating portion 25 may not be provided and the inside of the semiconductor pillar 20 may be filled up with the same material as that forming the semiconductor pillar 20.

A first conductive portion 50 extends in the stacked body LS. An insulating layer 55 is provided between the first conductive portion 50 and the stacked body LS and between the first conductive portion 50 and the insulating layer 41. The first conductive portion 50 is connected to the p-type semiconductor region 12. A portion of the first conductive portion 50 and a portion of the insulating layer 55 are provided in the substrate S. One end of the first conductive portion 50 in the Z-direction comes into contact with the p-type semiconductor region 12. The one end of the first conductive portion 50 in the Z-direction overlaps the p-type semiconductor region 12 in the X-direction. The first conductive portion 50 functions as, for example, a first source line which is used to remove charge stored in the memory layer 30.

A second conductive portion 60 extends in the stacked body LS. An insulating layer 65 is provided between the second conductive portion 60 and the stacked body LS and between the second conductive portion 60 and the insulating layer 41. The second conductive portion 60 is connected to the n-type semiconductor region 13. A portion of the second conductive portion 60 and a portion of the insulating layer 65 are provided in the substrate S. One end of the second conductive portion 60 in the Z-direction comes into contact with, for example, the n-type semiconductor region 13. The one end of the second conductive portion 60 in the Z-direction overlaps the n-type semiconductor region 13 in the X-direction. The second conductive portion 60 functions as, for example, a second source line which is used to read charge stored in each memory cell.

The stacked body LS is divided in the X-direction by the first conductive portion 50 and the second conductive portion 60.

The bit line 80 is provided on the insulating layer 44. For example, as illustrated in FIG. 1, the bit line 80 extends in the X-direction. An insulating layer 45 is provided on the bit line 80.

As illustrated in FIG. 2, a plurality of first conductive portions 50 and a plurality of second conductive portions 60 are provided in the X-direction. Each of the first conductive portions 50 and each of the second conductive portions 60 extend in the Y-direction. At least a portion of the semiconductor pillar 20 and at least a portion of the memory layer are provided between the first conductive portion 50 and the second conductive portion 60.

A plurality of memory strings MS are provided in the X-direction and the Y-direction. Two rows of the memory strings MS arranged in, for example, the Y-direction are provided between the first conductive portion 50 and the second conductive portion 60 which are adjacent to each other in the X-direction. One row or three or more rows of the memory strings MS arranged in the Y-direction may be provided between the first conductive portion 50 and the second conductive portion 60.

A plurality of memory strings MS provided between adjacent first conductive portions 50 form one block in which an erasing operation of erasing information stored in the memory cells is collectively performed.

A plurality of bit lines 80 are provided in the Y-direction. The semiconductor pillars 20 provided between the first conductive portion 50 and the second conductive portion 60 which are adjacent to each other are connected to different bit lines 80.

A plurality of p-type semiconductor regions 12 and a plurality of n-type semiconductor regions 13 are provided in the X-direction. The p-type semiconductor regions 12 and the n-type semiconductor regions 13 are alternately provided in the X-direction. The p-type semiconductor regions 12 and the n-type semiconductor regions 13 extend in the Y-direction. The p-type semiconductor regions 12 may be successively provided in the X-direction. That is, two or more p-type semiconductor regions 12 may be provided between the n-type semiconductor regions 13 which are adjacent to each other in the X-direction.

The length L1 of the p-type semiconductor region 12 in a direction (X-direction) from the p-type semiconductor region 12 to the n-type semiconductor region 13 is greater than, for example, the length L2 of the n-type semiconductor region 13 in the X-direction. The length L1 is greater than, for example, the length L3 of the first conductive portion 50 in the X-direction. The length L2 is greater than, for example, the length L4 of the second conductive portion 60 in the X-direction.

As illustrated in FIG. 3A, the memory layer 30 includes a block layer 31, a charge storage layer 32, and a tunnel layer 33. The tunnel layer 33 is provided between the semiconductor pillar 20 and the stacked body LS. The charge storage layer 32 is provided between the tunnel layer 33 and the stacked body LS. The block layer 31 is provided between the charge storage layer 32 and the stacked body LS.

Alternatively, as illustrated in FIG. 3B, the memory layer 30 may not include the block layer 31 and the stacked body LS may include the block layer 31. In this case, a portion of the block layer 31 is provided between a conductive layer 40 and the insulating layer 45 and another portion of the block layer 31 is provided between the conductive layer 40 and the charge storage layer 32.

The semiconductor pillar 20 functions as a region in which a channel is formed. The conductive layer 42 functions as a control gate of the memory cell. The charge storage layer 32 functions as a data memory layer which stores charge injected from the semiconductor pillar 20. That is, the memory cell having the structure in which the control gate surrounds the channel is formed in an intersection portion between the semiconductor pillar 20 and each conductive layer WL.

The block layer 31 is an insulating layer and prevents the charge stored in the charge storage layer 32 from being diffused to the conductive layer WL. The block layer 31 is, for example, a silicon oxide layer.

The charge storage layer 32 includes a large number of trap sites for capturing charge. The charge storage layer 32 is, for example, a silicon nitride layer.

The tunnel layer 33 is an insulating layer. The tunnel layer 33 functions as a potential barrier when charge is injected from the semiconductor pillar 20 to the charge storage layer 32 or when the charge stored in the charge storage layer 32 is diffused to the semiconductor pillar 20. The tunnel layer 33 is, for example, a silicon oxide layer.

As illustrated in FIG. 4, one end of the memory layer 30 in the Z-direction is provided in, for example, the n-type semiconductor region 11. That is, the one end of the memory layer 30 overlaps the n-type semiconductor region 11 in the X-direction.

Similarly, one end of the semiconductor pillar 20 in the Z-direction is provided in, for example, the n-type semiconductor region 11. That is, the one end of the semiconductor pillar 20 overlaps the n-type semiconductor region 11 in the X-direction. The one end of the semiconductor pillar 20 in the Z-direction comes into direct contact with, for example, the n-type semiconductor region 11.

The length L6 of a portion of the semiconductor pillar 20, which is provided in the n-type semiconductor region 11, in the Z-direction is greater than, for example, the length L5 of a portion of the memory layer 30, which is provided in the n-type semiconductor region 11, in the Z-direction.

FIG. 4 illustrates an aspect in which the memory layer 30 has the structure illustrated in FIG. 3A. In FIG. 4, the memory layer 30 may have the structure illustrated in FIG. 3B.

Next, an example of the operation of the semiconductor memory device 100 will be described.

When information stored in the memory cell is read, a positive voltage is applied to the bit line 80 connected to the memory string MS including a target memory cell. A voltage that is equal to or greater than a threshold value is applied to the conductive layers 42 other than the conductive layer 42 of the target memory cell to form a channel CH1 in the semiconductor pillar 20, as illustrated in FIG. 4. A determination voltage that is less than the threshold value is applied to the conductive layer 42 of the target memory cell. In this case, the value of a current which flows from the n-type semiconductor region 11 to the bit line 80 is detected to determine whether charge is stored in the target memory cell.

When charge is stored in the memory cell to store information, a positive voltage is applied to the conductive layers 42 of the memory string MS including the target memory cell and the bit line 80 connected to the memory string MS. A voltage that is higher than the voltage applied to the bit line 80 is applied to the conductive layer 42 of the target memory cell to store charge in the target memory cell. In this way, information is stored in the target memory cell.

When the information stored in the memory cell is erased, a positive voltage is applied to the bit line 80 and the first conductive portion 50 connected to a block including the target memory cell to maintain the voltage of the conductive layer 42 at 0 V. In this case, as illustrated in FIG. 4, a channel CH2 is formed in a region of the n-type semiconductor region 11 which is provided in the vicinity of the insulating layer 41. When a hole is injected into the charge storage layer 32 through the channel CH1 and the channel CH2, the electron stored in the charge storage layer 32 is removed and the information stored in the memory cell is erased.

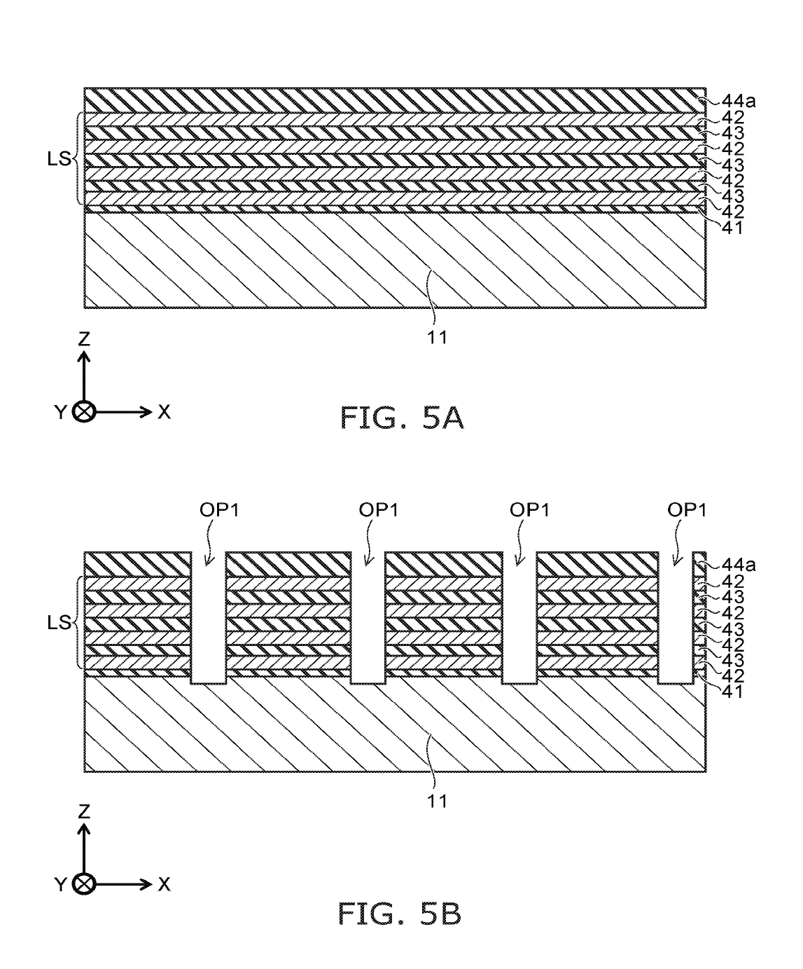

Next, a method for manufacturing the semiconductor memory device 100 according to the embodiment will be described with reference to FIG. 5A to FIG. 11B. FIG. 5A to FIG. 11B are cross-sectional views of a manufacturing process of the semiconductor memory device 100 according to the embodiment.

A semiconductor substrate is prepared. The main component of the semiconductor substrate is, for example, Si. Then, n-type impurity ions are implanted into the surface of the substrate to form the n-type semiconductor region 11. For example, phosphorus or arsenic can be used as the n-type impurities.

The insulating layer 41 is formed on the n-type semiconductor region 11. The conductive layers 42 and the insulating layers 43 are alternately formed on the insulating layer 41. As illustrated in FIG. 5A, an insulating layer 44a is formed on the uppermost conductive layer 42. Each layer is formed by, for example, a CVD (chemical vapor deposition) method. The insulating layer 41, the insulating layer 43, and the insulating layer 44 include, for example, a silicon oxide. The conductive layer 42 includes, for example, polysilicon doped with p-type or n-type impurities. For example, boron can be used as the p-type impurities.

As illustrated in FIG. 5B, an opening OP1 is formed so as to extend in the insulating layer 41, the plurality of conductive layers 42, the plurality of insulating layers 43, and the insulating layer 44a. The opening OP1 is formed by, for example, a photolithography method and an RIE (reactive ion etching) method. A plurality of openings OP1 are formed in the X-direction. In this case, a portion of the surface of the n-type semiconductor region 11 is removed by, for example, the RIE method.

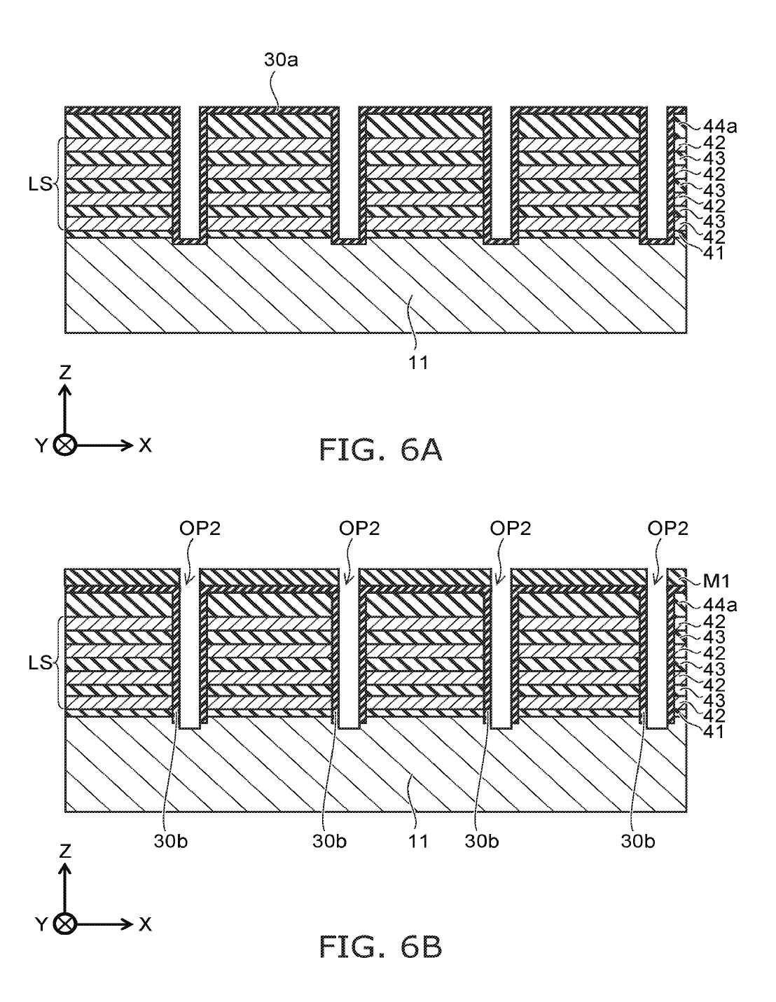

As illustrated in FIG. 6A, a memory layer 30a is formed on the upper surface of the insulating layer 44a and the inner wall of the opening OP1. A portion of the memory layer 30a which is located at the bottom of the opening OP1 is formed on the n-type semiconductor region 11.

A mask M1 is formed above a region other than the region in which the opening OP1 is formed in the stacked body LS. As illustrated in FIG. 6B, a portion of the memory layer 30a which is located at the bottom of the opening OP1 is removed by, for example, the RIE method using the mask M1. In this case, a portion of the n-type semiconductor region 11 is removed. A memory layer 30b is formed and an opening OP2 is formed in the memory layer 30b by this process.

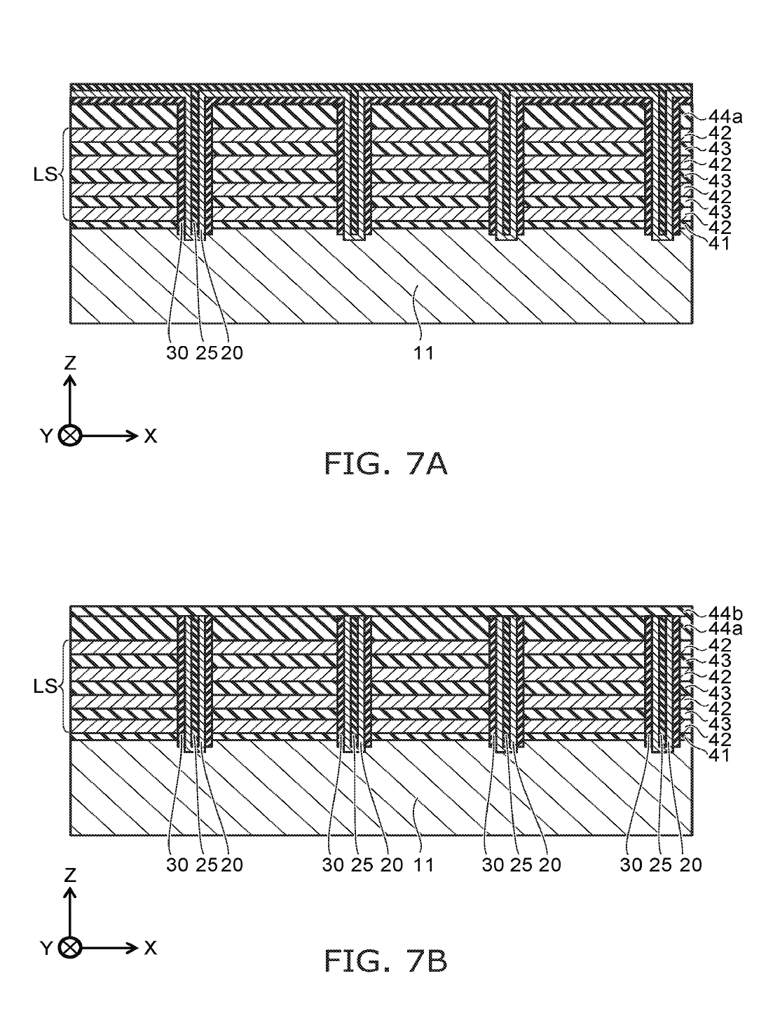

After the mask M1 is removed, a semiconductor layer 20a is formed on the inner wall of the opening OP2 and the memory layer 30b by, for example, the CVD method. An insulating layer 25a is formed on the semiconductor layer 20a. As illustrated in FIG. 7A, the opening OP2 is filled with the semiconductor layer 20a and the insulating layer 25a.

A portion of the memory layer 30b, a portion of the semiconductor layer 20a, and a portion of the insulating layer 25a which are formed on the insulating layer 44a are removed by, for example, a CMP (chemical mechanical polishing) method. The semiconductor pillar 20, the insulating portion 25, and the memory layer 30 which are separated from each other in the X-direction and the Y-direction are formed by this process. As illustrated in FIG. 7B, an insulating layer 44b is formed on the insulating layer 44a so as to cover the semiconductor pillar 20, the insulating portion 25, and the memory layer 30. The insulating layer 44b includes, for example, a silicon oxide and is formed by the CVD method.

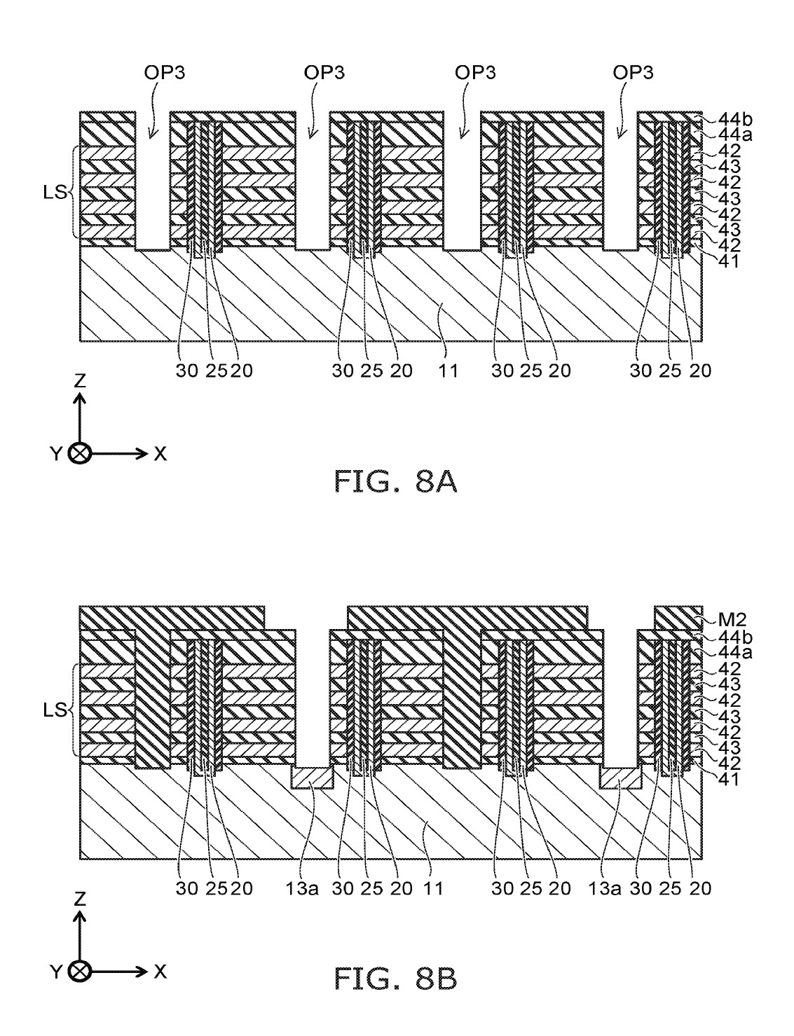

As illustrated in FIG. 8A, for example, openings OP3 are formed by the photolithography method and the RIE method. The opening OP3 is formed at a position different from the position where the semiconductor pillar 20, the insulating portion 25, and the memory layer 30 are formed. A plurality of openings OP3 are formed in the X-direction.

A mask M2 is formed so as to cover some of the openings OP3. As illustrated in FIG. 8B, n-type impurity ions are implanted into a portion of the n-type semiconductor region 11 which is located below the bottom of the opening OP3 that is not covered with the mask M2. A semiconductor region 13a is formed by this process.

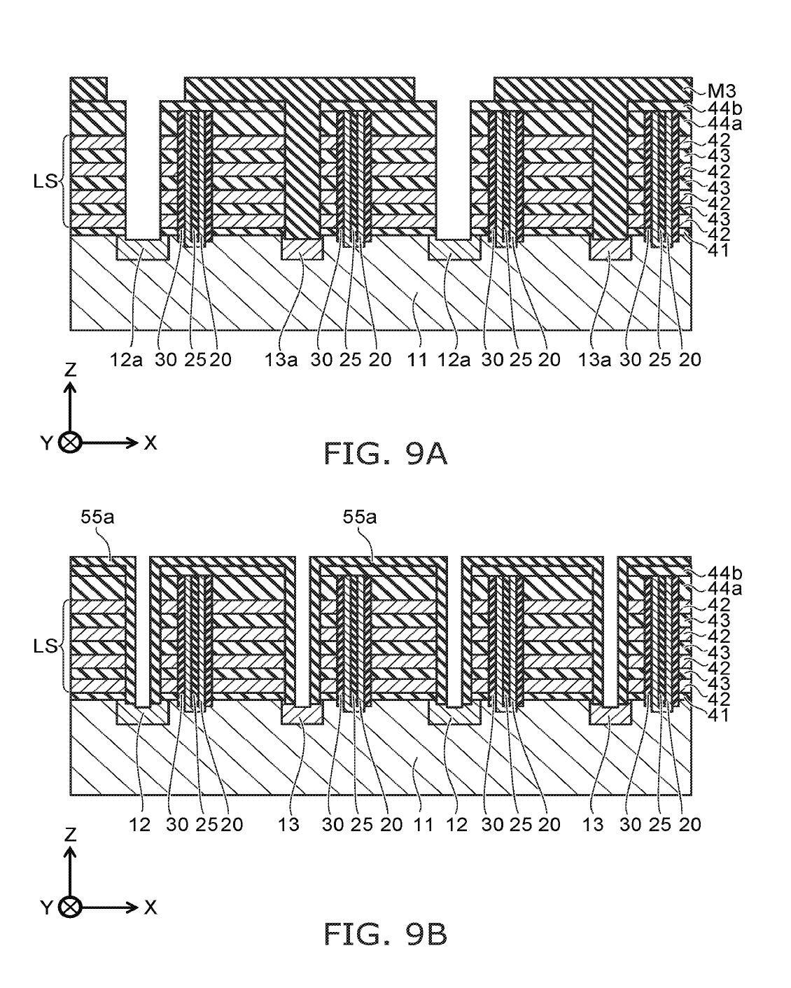

The mask M2 is removed. A mask M3 is formed so as to cover the opening OP3 which has not been covered with the mask M2. The opening OP3 which has been covered with the mask M2 is not covered with the mask M3. As illustrated in FIG. 9A, p-type impurity ions are implanted into a portion of the n-type semiconductor region 11 which is located below the bottom of the opening OP3 that is not covered with the mask M3. A semiconductor region 12a is formed by this process.

A heating process is performed to activate the impurities implanted into each region. As a result, the p-type semiconductor region 12 and the n-type semiconductor region 13 are formed. The heating process may be performed whenever impurity ions are implanted.

The mask M3 is removed. As illustrated in FIG. 9B, an insulating layer 55a is formed on the inner wall of the opening OP3 formed in the insulating layer 44 and on the insulating layer 44. The insulating layer 55a includes, for example, a silicon oxide.

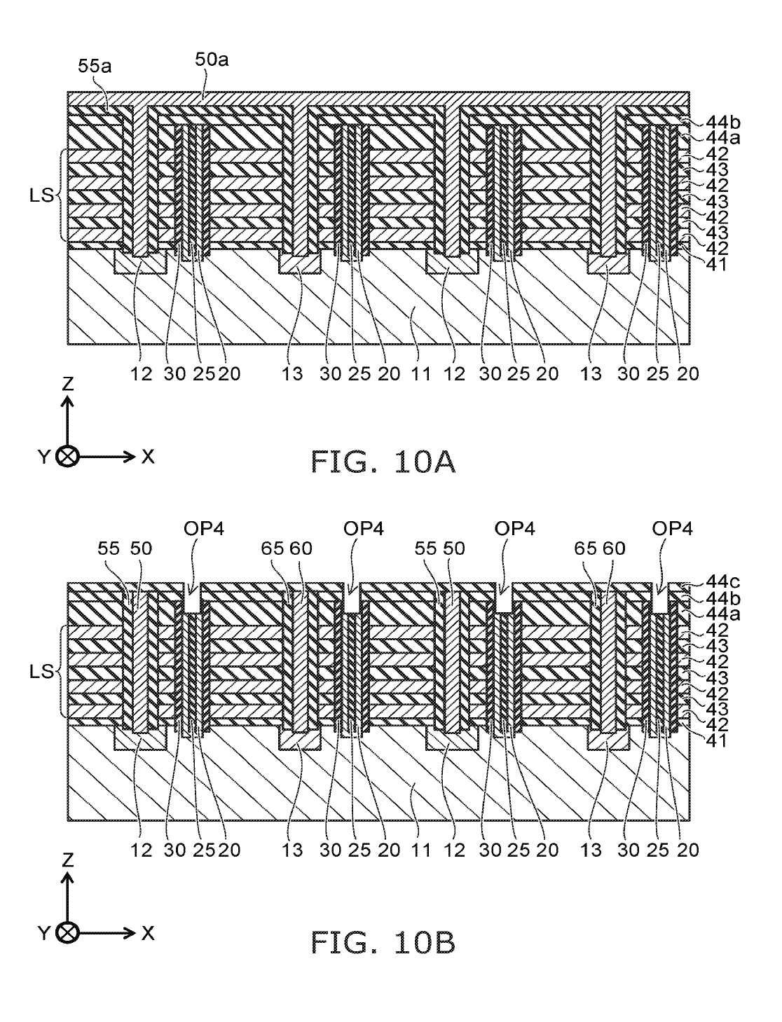

As illustrated in FIG. 10A, a metal layer 50a is formed on the insulating layer 55a. The metal layer 50a includes, for example, tungsten. Each opening OP3 is filled with the insulating layer 55a and the metal layer 50a.

A portion of the insulating layer 55a and a portion of the metal layer 50a are removed by the CMP method. The first conductive portion 50, the insulating portion 50, the second conductive portion 60, and the insulating portion 65 illustrated in FIG. 1 are formed by this process. An insulating layer 44c is formed on the insulating layer 44b so as to cover the first conductive portion 50, the insulating portion 50, the second conductive portion 60, and the insulating portion 65. The insulating layer 44c includes, for example, a silicon oxide. The insulating layers 44a, 44b, and 44c form the insulating layer 44 illustrated in FIG. 1.

As illustrated in FIG. 10B, an opening OP4 is formed at a position corresponding to the position of the semiconductor pillar 20. The opening OP4 is formed by, for example, the photolithography method and the RIE method. The opening OP4 extends in the insulating layer 44b and the insulating layer 44c.

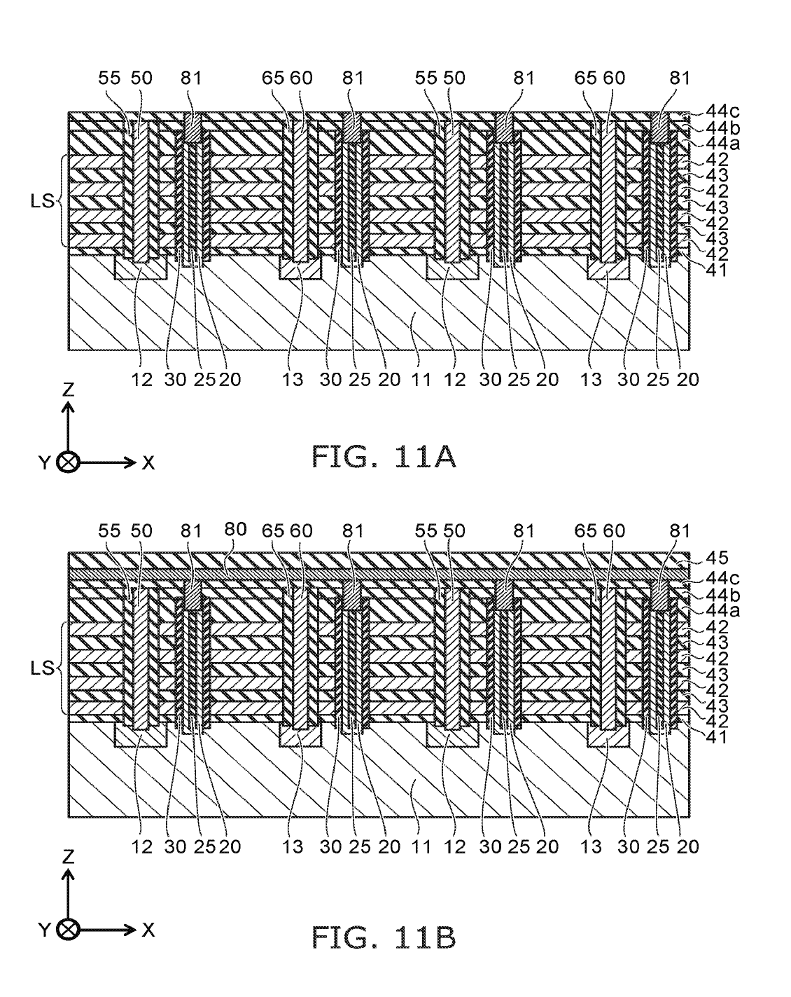

A metal layer is formed on the insulating layer 44c such that the opening OP4 is filled with the metal layer. The metal layer includes, for example, tungsten. A surplus metal layer on the insulating layer 44c is removed. In this way, a contact plug 81 buried in the opening OP4 is formed as illustrated in FIG. 11A.

A metal layer is formed on the insulating layer 44c. The metal layer includes, for example, copper. The metal layer is patterned by, for example, the photolithography method and the RIE method to form the bit line 80. The insulating layer 45 is formed so as to cover the bit line 80.

The semiconductor memory device 100 illustrated in FIG. 1 to FIG. 4 is fabricated by the above-mentioned processes.

According to the embodiment, it is possible to accurately read information stored in the semiconductor memory device. The reason is that, when a reading operation is performed, a current flows between the n-type semiconductor region 11 and the bit line 80.

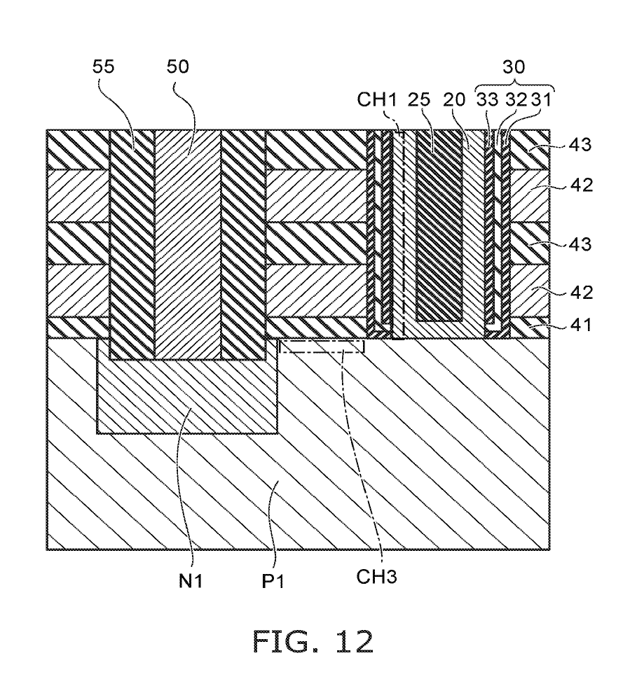

A comparative example of the embodiment is illustrated in FIG. 12. FIG. 12 is a cross-sectional view of a semiconductor memory device according to the comparative example. The comparative example illustrated in FIG. 12 includes a p-type semiconductor region P1 and an n-type semiconductor region N1 which is provided on the p-type semiconductor region P1. A first conductive portion 50 is connected to the n-type semiconductor region N1 and a semiconductor pillar 20 is connected to the p-type semiconductor region P1.

In the comparative example, when a reading process is performed for a memory cell, first, a positive voltage is applied to a bit line (not illustrated) connected to the semiconductor pillar 20 and the first conductive portion 50. A voltage is applied to conductive layers 42 of a memory string MS including a target memory cell and a determination voltage is applied to the conductive layer 42 of the memory cell to be subjected to a reading process. A channel CH1 is formed in the semiconductor pillar 20 by the voltage applied to the conductive layer 42. When a voltage is applied to a conductive layer 42 adjacent to an insulating layer 41, a channel CH3 is formed in a region of the p-type semiconductor region P1 which is arranged in the vicinity of the insulating layer 41. An electron flows from the first conductive portion 50 to the bit line through the channel CH1 and the channel CH3.

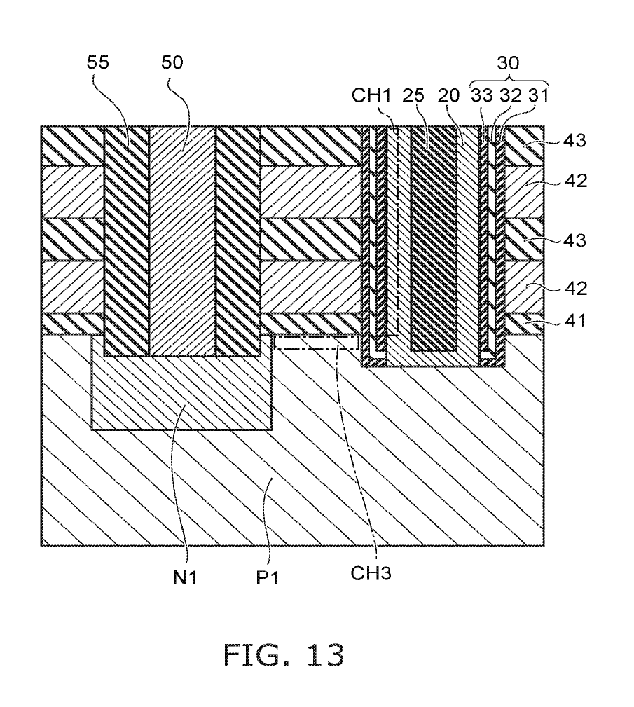

However, when a memory layer 30 and the semiconductor pillar 20 are formed, a portion of the surface of the p-type semiconductor region P1 is likely to be removed by etching. An aspect in this case is illustrated in FIG. 13. FIG. 13 is a diagram for describing the problems of the semiconductor memory device according to the comparative example which were examined by the inventors when the inventors conceived the embodiment. When a portion of the surface of the p-type semiconductor region P1 is removed by etching, a portion of the memory layer 30 is formed in the p-type semiconductor region P1 as illustrated in FIG. 13. When a portion of the memory layer 30 is formed in the p-type semiconductor region P1, the portion of the memory layer 30 is located between the channel CH2 and the channel CH3. Therefore, the movement of the electron which flows from the first conductive portion 50 to the bit line is hindered. As a result, in some cases, information stored in the memory cell is not read or the information stored in the memory cell is erroneously read.

In contrast, according to the embodiment, when information stored in the memory cell is read, a carrier flows between the n-type semiconductor region 11 and the bit line 70. Therefore, even when a portion of the memory layer 30 is formed in the n-type semiconductor region 11, the movement of the electron is not hindered by the portion of the memory layer 30. As a result, according to the embodiment, it is possible to more accurately read the information stored in the memory cell than the comparative example illustrated in FIG. 12.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Moreover, above-mentioned embodiments can be combined mutually and can be carried out.

What is claimed is:

1. A semiconductor memory device comprising:
a first semiconductor region of n-type conductivity;
a second semiconductor region of p-type conductivity being provided on the first semiconductor region;
a third semiconductor region of n-type conductivity being provided on the first semiconductor region with separation from the second semiconductor region;
a stacked body being provided on the semiconductor layer, the stacked body including a plurality of conductive layers and a plurality of insulating layers, the plurality of conductive layers and the plurality of insulating layers being alternately provided;
a semiconductor pillar extending in the stacked body in a direction in which the plurality of conductive layers and the plurality of insulating layers are stacked, the semiconductor pillar being connected to the first semiconductor region;
a first insulating layer being provided between the stacked body and the semiconductor pillar;
a charge storage layer being provided between the stacked body and the first insulating layer;
a second insulating layer, at least a portion of the second insulating layer being provided between the stacked body and the charge storage layer;
a first conductive portion extending in the stacked body in the stacking direction, the first conductive portion being connected to the second semiconductor region; and
a second conductive portion extending in the stacked body in the stacking direction, the second conductive portion being connected to the third semiconductor region.

2. The device according to claim 1, wherein
a p-type carrier density of the second semiconductor region is higher than an n-type carrier density of the first semiconductor region, and
an n-type carrier density of the third semiconductor region is higher than the n-type carrier density of the first semiconductor region.

3. The device according to claim 2, wherein
a length of the second semiconductor region in a first direction is greater than a length of the third semiconductor region in the first direction,
the first direction is from the second semiconductor region toward the third semiconductor region, and
the first direction is perpendicular to the stacking direction.

4. The device according to claim 3, wherein
a p-type carrier density of the second semiconductor region is lower than an n-type carrier density of the third semiconductor region.

5. The device according to claim 1, wherein
at least a portion of the semiconductor pillar, at least a portion of the first insulating layer, and at least a portion of the charge storage layer are provided between the first conductive portion and the second conductive portion in a first direction,
the first direction is from the second semiconductor region toward the third semiconductor region,
the first direction is perpendicular to the stacking direction, and
the first conductive portion and the second conductive portion extend in a second direction that is perpendicular to the stacking direction and the first direction.

6. The device according to claim 1, wherein
a portion of the semiconductor pillar, a portion of the first insulating layer, a portion of the charge storage layer, and a portion of the second insulating layer overlap a portion of the first semiconductor region in a first direction,
the first direction is perpendicular to the stacking direction, and
the first conductive portion and the second conductive portion extend in a second direction that is perpendicular to the stacking direction and the first direction.

7. The device according to claim 1, wherein
the semiconductor pillar includes a first semiconductor portion that overlaps a portion of the first semiconductor region in a first direction,
the first insulating layer includes a first insulating portion that overlaps the portion of the first semiconductor region in the first direction,
a length of the first semiconductor portion in the stacking direction is greater than a length of the first insulating portion in the stacking direction,
the first direction is from the second semiconductor region toward the third semiconductor region, and
the first direction is perpendicular to the stacking direction.

8. The device according to claim 1, wherein
the semiconductor pillar includes a first semiconductor portion that overlaps a portion of the first semiconductor region in a first direction,
the second insulating layer includes a second insulating portion that overlaps the portion of the first semiconductor region in the first direction,
a length of the first semiconductor portion in the stacking direction is greater than a length of the second insulating portion in the stacking direction,
the first direction is from the second semiconductor region toward the third semiconductor region, and
the first direction is perpendicular to the stacking direction.

9. The device according to claim 1, wherein
the semiconductor pillar contacts with the first semiconductor region.

10. The device according to claim 1, wherein
the second insulating layer contacts with the first semiconductor region.

11. The device according to claim 1, wherein
a portion of the first conductive portion contacts with the second semiconductor region, and
a portion of the second conductive portion contacts with the third semiconductor region.

12. The device according to claim 11, wherein
the portion of the first conductive portion overlaps a portion of the second semiconductor region in a first direction,
the portion of the second conductive portion overlaps a portion of the third semiconductor region in the first direction,
the first direction is from the second semiconductor region toward the third semiconductor region, and
the first direction is perpendicular to the stacking direction.

13. The device according to claim 1, wherein
the second semiconductor region is provided in plurality,
the second semiconductor regions are arranged in a first direction that is perpendicular to the stacking direction,
the third semiconductor region is provided in plurality, and
the third semiconductor regions are arranged in the first direction.

14. The device according to claim 13, wherein
the second semiconductor regions and the third semiconductor region are alternately arranged in the first direction.

15. The device according to claim 13, wherein
at least two of the second semiconductor regions and the third semiconductor region are alternately arranged in the first direction.

16. The device according to claim 5, wherein
the semiconductor pillar is provided in plurality,
the semiconductor pillars are provided with separation from each other, and
the semiconductor pillars are provided between the first conductive portion and the second conductive portion in the first direction.

17. The device according to claim 16, wherein
the first insulating layer, the charge storage layer, and the second insulating layer are provided in plurality,
each of the first insulating layers is provided between each of the semiconductor pillars and the stacked body,
each of the charge storage layers is provided between each of the first insulating layers and the stacked body, and
each of the second insulating layers is provided between each of the charge storage layers and the stacked body.
